(19) United States
(12) Patent Application Publication
(10) Pub. No.: US 2019/0015873 A1
(43) Pub. Date: Jan. 17, 2019

(54) METHODS AND SYSTEMS FOR SORTING A PLURALITY OF COMPONENTS FOR DIRECTED SELF-ASSEMBLY

(71) Applicant: SelfArray, Inc., Troy, NY (US)

(72) Inventor: Mark DURNIAK, Lafayette, CO (US)

(73) Assignee: SelfArray, Inc., Troy, NY (US)

(21) Appl. No.: 16/032,292

(22) Filed: Jul. 11, 2018

Related U.S. Application Data
(60) Provisional application No. 62/531,512, filed on Jul. 12, 2017.

(51) Int. Cl. B07C 5/38; H01L 33/48; H01L 33/02; G01R 31/28; G01R 31/26; B07C 5/344; B07C 5/342; B07C 5/36

(52) U.S. Cl. CPC B07C 5/38; H01L 33/48; H01L 33/02; B07C 5/362; G01R 31/2635; B07C 5/344; B07C 5/342; G01R 31/2831

(57) ABSTRACT

Methods for binning, or sorting a plurality of components for directed self-assembly are provided. One method includes, for instance: providing a mapped wafer suspended in a mounting assembly; selecting at least one of the plurality of components for removal based on a set of parameters; moving at least one of an actuated impulse source and the mounting assembly to align the actuated impulse source and the at least one of the plurality of components; and removing the at least one of the plurality of components using the actuated impulse source, the removed at least one of the plurality of components falling into a bin below, the at least one of the plurality of components falling in any orientation.

### CROSS-REFERENCE TO RELATED APPLICATION

This application claims priority benefit under 35 U.S.C. § 119(e) to U.S. Provisional Application No. 62/531,512, filed 12 Jul. 2017, and entitled METHODS AND SYSTEMS FOR BINNING OR SORTING A PLURALITY OF COMPONENTS FOR DIRECTED SELF-ASSEMBLY, the entirety of which is incorporated herein by reference in its entirety.

### FIELD OF THE INVENTION

The present invention relates to methods and systems for binning, or sorting, a plurality of components for directed self-assembly, and more particularly, to sorting light emitting diode dies for directed self-assembly directly from a diced wafer into bins.

### BACKGROUND

Binning of components by characteristic, and more particularly, the binning of light emitting diodes (LEDs) by categories such as wavelength, brightness, and forward voltage, is critical to final system uniformity and performance. Current methods of binning and sorting components, such as light emitting diodes (LEDs), can be slow due to the fact that each individual component must be tested and then placed in a specific location, requiring fine manipulation tools. For larger scale displays, sorting and binning time of LED components increases processing time and cost. However, in the case of LEDs, every LED die on a wafer is completely tested prior to singulation, or dicing. The results of this test can be used to later sort the components, but traditional methods still require a relatively slow transfer mechanism as the sorted die are required to be placed in a specific location and orientation after sorting.

It may be desirable to develop faster methods of binning components for directed self-assembly to increase throughput and handle components more efficiently and effectively.

### BRIEF SUMMARY

The shortcomings of the prior art are overcome and additional advantages are provided through the provisions, in one aspect, a method that includes, for instance: providing a mapped wafer suspended in a mounting assembly; selecting at least one of the plurality of components for removal based on a set of parameters; moving at least one of an actuated impulse source and the mounting assembly to align the actuated impulse source and the at least one of the plurality of components; removing the at least one of the plurality of components using the actuated impulse source, the removed at least one of the plurality of components falling into a bin below, the at least one of the plurality of components falling in any orientation.

Also disclosed is a system, in one aspect, that includes: a mounting assembly for containing and moving a mapped wafer comprising a plurality of components; an actuated impulse source; and a bin, wherein the bin receives at least one of the plurality of components in any orientation when removed from the wafer using the actuated impulse source.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts one embodiment of a method of binning a plurality of components for directed self-assembly, in accordance with one or more aspects of the present invention;

FIG. 2 depicts a top view of one embodiment of a system including a tested, mapped, and singulated wafer attached to a mounting surface suspended in a mounting assembly, an actuated impulse source located above the mounting assembly, and a bin beneath the mounting assembly component, in accordance with one or more aspects of the present invention;

FIG. 3 depicts a cross-sectional elevation view of one embodiment of a system including a tested, mapped, and singulated wafer attached to a mounting surface suspended in a mounting assembly, an actuated impulse source located above the mounting assembly, and a bin beneath the mounting assembly component, in accordance with one or more aspects of the present invention;

FIG. 4 depicts a top view of one embodiment of a system including alignment of the actuated impulse source with the selected component for directed self assembly by moving the mounting frame and/or the actuated impulse source, and an impulse acting on the selected component propelling it into the bin below, in accordance with one or more aspects of the present invention; and

FIG. 5 depicts a cross-sectional elevation view of one embodiment of a system including alignment of the actuated impulse source with the selected component for directed self assembly by moving the mounting frame and/or the actuated impulse source, and an impulse acting on the selected component propelling it into the bin below, in accordance with one or more aspects of the present invention.

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure. Note also that reference is made below to the drawings, which are not drawn to scale for ease of understanding, wherein the same reference numbers used throughout different figures designate the same or similar components.

Generally stated, disclosed herein are methods and systems for binning and sorting a plurality of components for directed self-assembly. Advantageously, the methods allow for faster and more efficient sorting of components, in some instances ferromagnetic or diamagnetic components. In some embodiments, since the components are to be used for directed self-assembly, the requirement for precise placement after binning is eliminated, and the components can be placed randomly into a bin in any orientation.

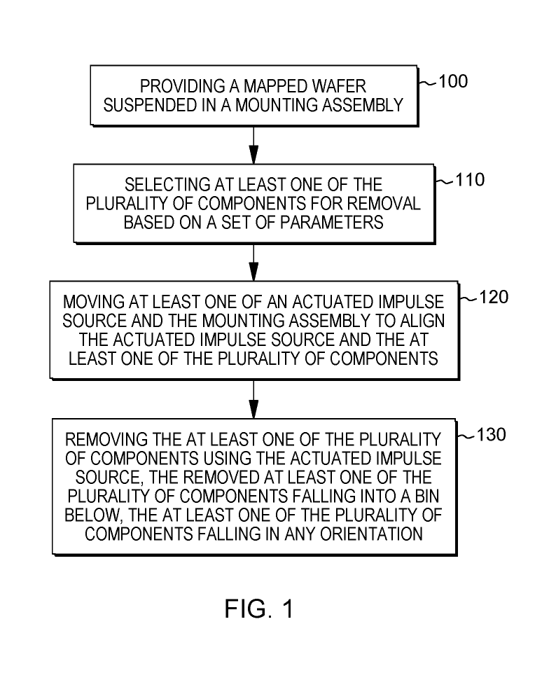

In one aspect, in one embodiment, as shown in FIG. 1, a method of binning or sorting a plurality of components for directed self-assembly may include providing a mapped wafer suspended in a mounting assembly 100; selecting at least one of the plurality of components for removal based on a set of parameters 110; moving at least one of an actuated impulse source and the mounting assembly to align the actuated impulse source and the at least one of the plurality of components 120; and removing the at least one of the plurality of components using the actuated impulse source, the removed at least one of the plurality of components falling into a bin below, the at least one of the plurality of components falling in any orientation 130.

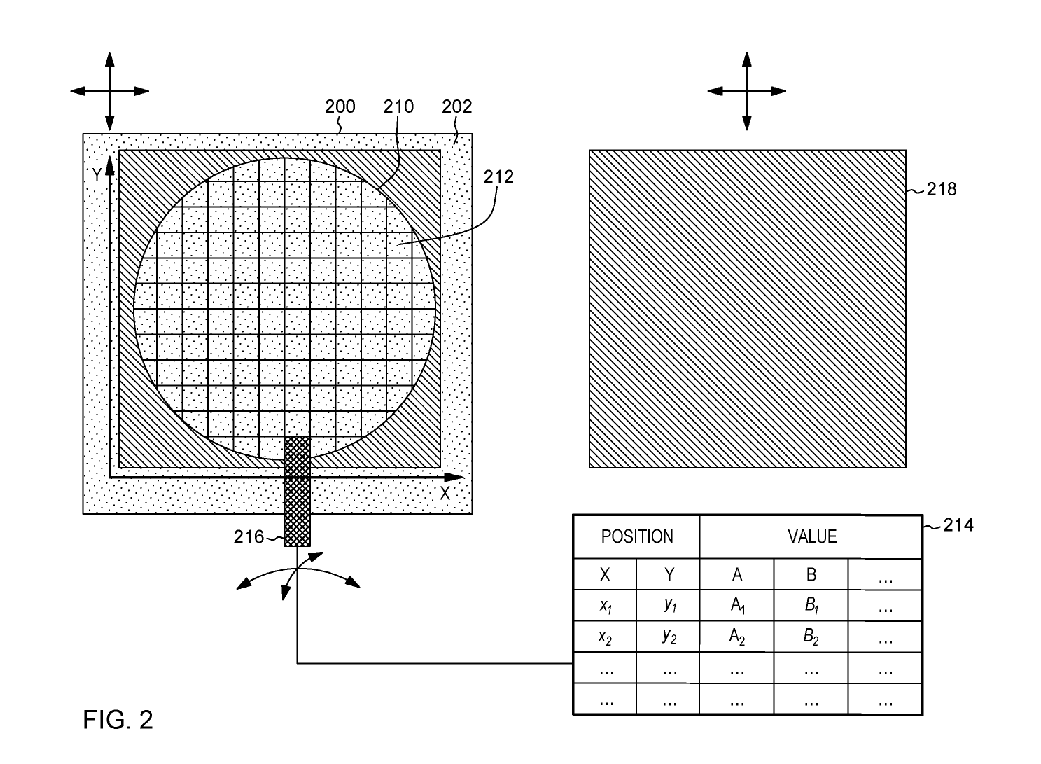

An example of a system useful for the methods disclosed herein is depicted in FIG. 2, including a moveable mounting assembly 200 for containing and moving a wafer 210 including a plurality of components 212 for directed self-assembly. In some embodiments, the wafer 210 can include a tested, mapped, and singulated wafer. The wafer may be on a mounting surface 202, which can be suspended from or in a mounting assembly 200, such as a frame for holding the mounting assembly 200, a map 214 of the positions within the wafer and parameter values for each component, an actuated impulse device 216, and a set of moveable bins 218 which can be positioned beneath the mounting assembly. The components 212 can, for example, be ferro- or dia-magnetic components for magnetically assisted directed self-assembly, or any other component for directed self-assembly known to those skilled in the art. The mounting surface 202 can be, for example, dicing tape, or any other material known to those skilled in the art. The map 214 can be a digital file consisting of the position and parameter values of each component on the wafer, for example, with LEDs the parameter values can include but are not limited to peak wavelength, wavelength full-width-at-half-max, brightness at varying operating currents, forward voltage, and reverse bias leakage current. The actuated impulse device 216 used to propel components from the mounting surface into the bin 218 below can consist of, for example, a laser, pin-pusher, air jet, or any other suitable impulse source known to those skilled in the art.

In another embodiment, rather than a wafer 210 being mounted on a mounting surface 202, the mapped wafer can be entirely transferred to a mounting surface 202, including some or all of the components 212. Although not illustrated, the figures would remain the same, as the transfer would have the same appearance. In some embodiments, when the components 212 are transferred to mounting surface 202, the mounting surface can include tape, a non-laser absorbing substrate or surface, or a substrate. In some embodiments, the adhesive used to attach the components 212 to the mounting surface 202 may fail under a laser or enough pressure, or the adhesive may be weak enough to allow a small force to remove components 212. Additionally, the adhesive may be such that it blisters upon exposure to a laser, causing components 212 to be removed from the mounting surface 202. These adhesives can also be used in embodiments where the wafer 210 is attached to the mounting surface 202, as well.

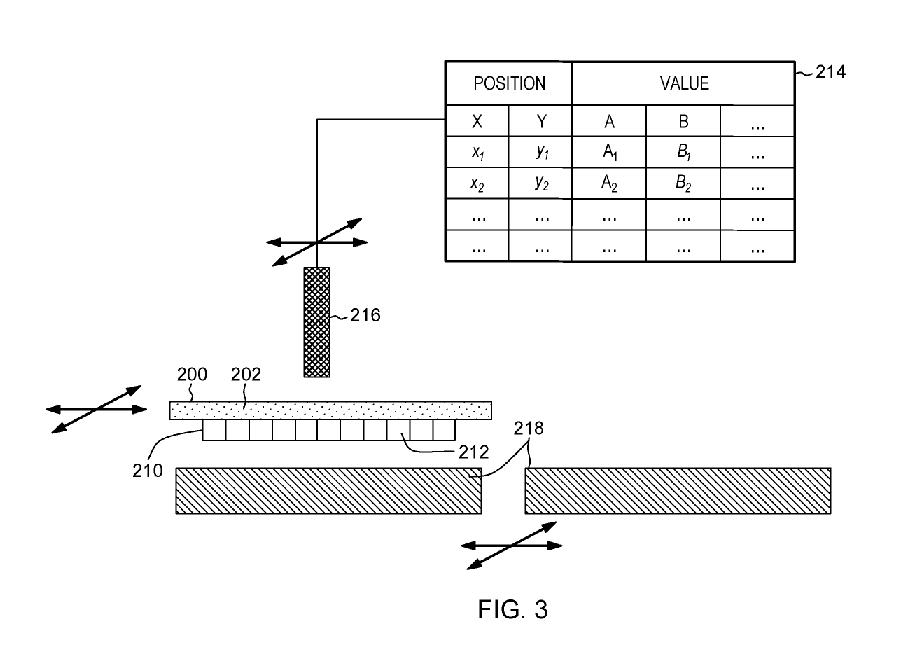

In a cross-sectional elevation view of the system depicted in FIG. 3, the wafer 210, is seen suspended from the mounting surface 202 within the moveable mounting frame 200, with bin 218 below, and actuated impulse device 216 above and connected to the map 214.

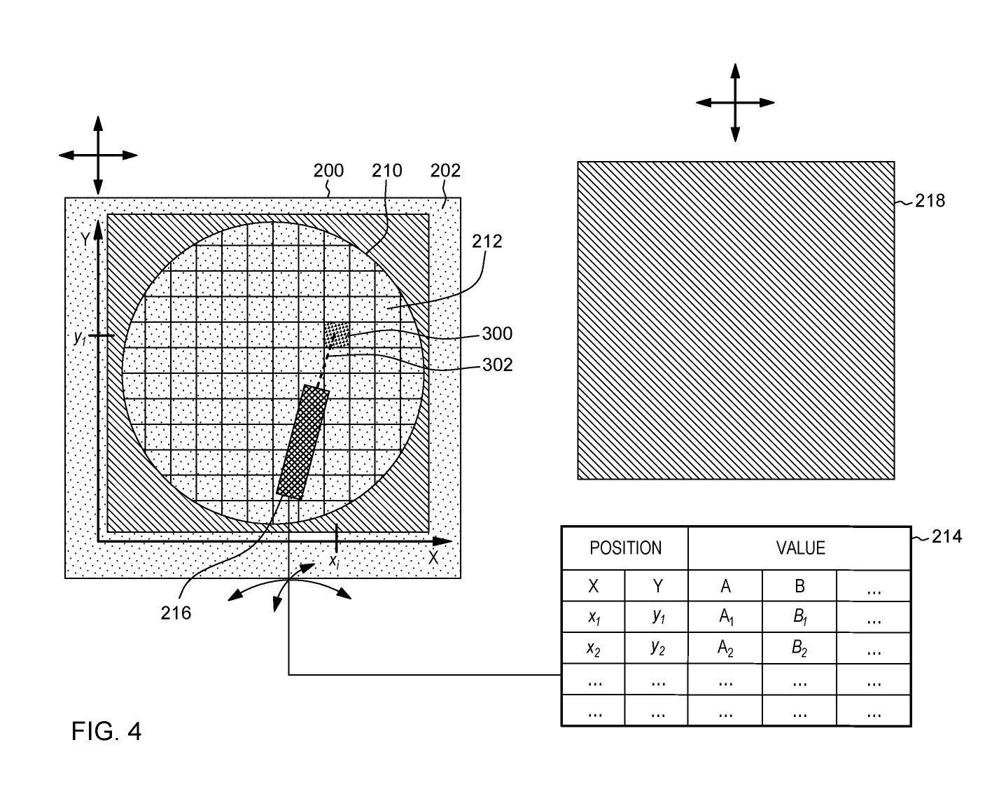

As seen in FIG. 4, when a bin 218 is selected, the map 214 is searched to identify all components with parameters that fit into that particular bin, which can include one or more of the known parameters being within a certain threshold or thresholds, hereby denoted as components of interest 300. The actuated impulse device 216 is aligned to the component of interest 300. In the case where the actuated impulse device is a pin-pusher or air jet alignment can be achieved by moving the mounting frame 200, actuated impulse device 216, or both. In the case where the actuated impulse device 216 is a laser, alignment can be achieved by aiming the laser at the component of interest 300, with or without any movement of actuated impulse device 216 or mounting frame 200. The actuated impulse device 216 then applies an impulse force 302 to the component of interest, propelling it from the mounting surface 202 and into the bin 218 below.

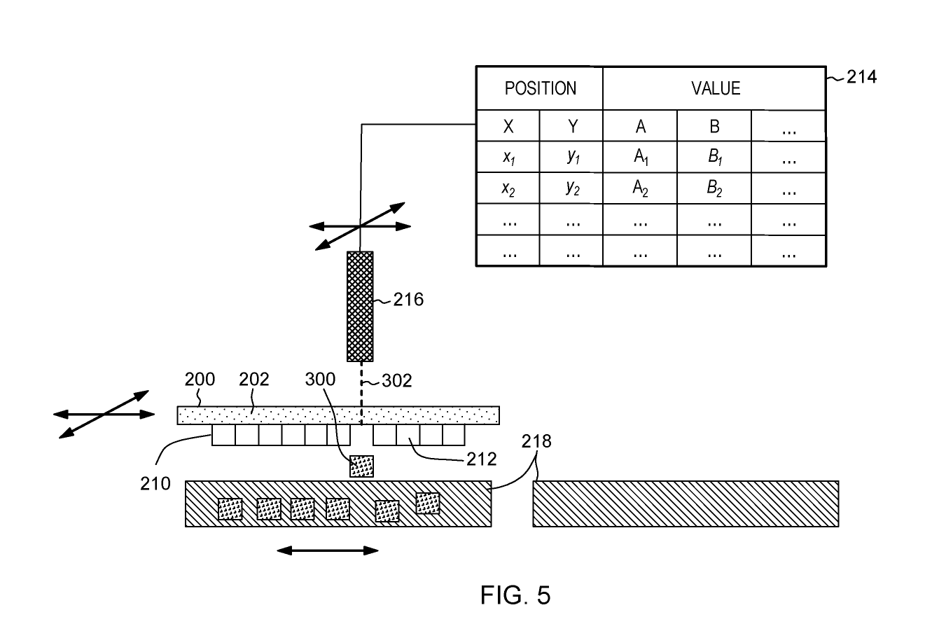

This process is seen in a cross-sectional elevation view in FIG. 5. The impulse force 302 is transmitted through the mounting surface 202, and causes the component of interest 300 to be propelled away from the mounting surface 202 and into the bin below 218, which contains all components within the same range of parameters chosen. The position of these components of interest 300 within the bin 218 is random which is suitable for components for directed self-assembly as further processing steps will orient them.

The process depicted in FIGS. 4 and 5 is repeated for all components of interest 300 within the wafer 210, until no more components that fit the bin 218 below remain on the wafer 210 and all are in the bin 218. At this point the current bin 218 is removed and a new bin 218 is brought into place. A new set of sorting parameters is selected and the process is repeated until all bins 218 are accounted for. Any components remaining on the mounting surface 202 after all the sorting steps are placed into a final bin for those that do not meet any of the required specifications.

Thus, a quick and efficient method and system is provided for binning, or sorting, of a plurality or set of components for directed self-assembly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A system for sorting a plurality of components, the system comprising:
a mounting assembly for containing and moving a mapped wafer comprising a plurality of components;
an actuated impulse source; and
a bin, wherein the bin receives at least one of the plurality of components in any orientation when removed from the wafer using the actuated impulse source.

2. The system of claim 1, further comprising:
at least one computing device in communication with the actuated impulse source and the mounting assembly, the at least one computing device including a map of the mapped wafer.

3. The system of claim 2, wherein the map comprises a digital file including a position for each of the plurality of components.

4. The system of claim 3, wherein the map includes a set of parameters for each of the plurality of components.

5. The system of claim 4, wherein the set of parameters includes at least one of: a peak wavelength, a wavelength full-width-at-half-max, a brightness for a plurality of operating currents, a forward voltage, and a reverse bias leakage current.

6. The system of claim 1, wherein the actuated impulse source comprises a laser, a pin-pusher, or an air jet.

7. The system of claim 6, wherein the mapped wafer includes a mounting surface.

8. The system of claim 7, wherein the mounting surface comprises dicing tape.

9. The system of claim 1, further comprising:
at least one second bin, wherein each at least second bin is utilized to receive a different at least one component based on at least one second set of parameters.

10. A method for sorting a plurality of components, the method comprising:
providing a mapped wafer suspended in a mounting assembly;
selecting at least one of the plurality of components for removal based on a set of parameters;
moving at least one of an actuated impulse source and the mounting assembly to align the actuated impulse source and the at least one of the plurality of components; and
removing the at least one of the plurality of components using the actuated impulse source, the removed at least one of the plurality of components falling into a bin below, the at least one of the plurality of components falling in any orientation.

11. The method of claim 10, the selecting further comprising:
the actuated impulse source and the mounting assembly communicating with at least one computing device, the at least one computing device including a map of the mapped wafer.

12. The method of claim 11, wherein the map comprises a digital file including a position for each of the plurality of components.

13. The method of claim 12, wherein the map includes the set of parameters for each of the plurality of components.

14. The method of claim 13, wherein the set of parameters includes at least one of: a peak wavelength, a wavelength full-width-at-half-max, a brightness for a plurality of operating currents, a forward voltage, and a reverse bias leakage current.

15. The method of claim 10, wherein the actuated impulse source comprises a laser, a pin-pusher, or an air jet.

16. The method of claim 15, wherein the mapped wafer includes a mounting surface.

17. The method of claim 16, wherein the mounting surface comprises dicing tape.

18. The method of claim 10, further comprising:
removing the bin;
placing a second bin below the mounting assembly; and
removing a different at least one of the plurality of components fitting a different set of parameters.
